(19) United States
(12) Patent Application Publication
(10) Pub. No.: US 2016/0035746 A1
(43) Pub. Date: Feb. 4, 2016

(54) ARRAY SUBSTRATE, METHOD FOR MANUFACTURING THE SAME AND DISPLAY DEVICE

(71) Applicant: BOE TECHNOLOGY GROUP CO., LTD., Beijing (CN)

(72) Inventors: Xiangyong KONG, Beijing (CN); Jun CHENG, Beijing (CN)

(21) Appl. No.: 14/422,831

(22) PCT Filed: Aug. 8, 2014
(86) PCT No.: PCT/CN2014/083995

§ 371 Date: Feb. 20, 2015

(30) Foreign Application Priority Data
Oct. 17, 2013 (CN) 201310487699.4

(51) Int. Cl. H01L 27/12; H01L 27/32

(52) U.S. Cl. CPC H01L 27/124; H01L 27/3248; H01L 27/1288

(57) ABSTRACT

Disclosed is an array substrate, a method of manufacturing the same, and a display device in use of the array substrate. The array substrate includes a gate electrode layer and a pixel electrode layer on a substrate. The gate electrode layer and the pixel electrode layer are stacked in contact with each other. The pixel electrode layer includes a first part and a second part separated from each other, the gate electrode layer includes a first part. The first part of the gate electrode layer and the first part of the pixel electrode layer are positioned as face-to-face. The gate electrode includes the first part of the gate electrode layer and the first part of the pixel electrode layer, and the pixel electrode includes the second part of the pixel electrode layer. The patterns of gate electrode layer and pixel electrode layer are manufactured with the same mask, which reduces the number of masks.

### TECHNICAL FIELD

The present disclosure relates to an array substrate, a method for manufacturing the array substrate, and a display device.

### BACKGROUND

In recent years, with the fast development of display technologies, flat-panel displays have replaced the cumbersome CRT displays and become popular in people's daily life more and more. At present, known flat-panel displays include liquid crystal displays (LCDs) and organic light-emitting diode (OLED) displays. The above-mentioned flat-panel displays have advantages of small volume, low power consumption, no irradiation and occupy predominant position in present flat-panel display market.

On the array substrate of a flat-panel display, each pixel is provided with a switch for controlling the pixel, namely a thin film field effect transistor (TFT). The TFT comprises at least a gate electrode, a source electrode, a drain electrode, a gate insulating layer and an active layer. A driver circuit is used to control every pixel independently, so it will not influence on other pixels such as crosstalk.

A known array substrate used in the above-mentioned flat-panel display has a configuration illustrated in FIG. 1. The array substrate at least comprises a substrate 51, a gate electrode 52, a gate insulating layer 53, an active layer 54, an etching stop layer 55, a source electrode 56, a drain electrode 57, a passivation layer 58 and a pixel electrode 59. For the manufacturing of the array substrate, at least six different masks are used to form the respective layers of the array substrate. If the array substrate is used as a backplate of an OLED, a mask for manufacturing a pixel design layer (PDL) is further needed.

### SUMMARY

In one aspect, there is provided an array substrate, which comprises: a substrate; a gate electrode layer and a pixel electrode layer both formed on the substrate, wherein the gate electrode layer and the pixel electrode layer are stacked in contact with each other, the pixel electrode layer comprises a first part and a second part separated from each other, the gate electrode layer comprises a first part, the first part of the gate electrode layer and the first part of the pixel electrode layer are positioned as face-to-face; a gate electrode comprising the first part of the gate electrode layer and the first part of the pixel electrode layer, and a pixel electrode comprising the second part of the pixel electrode layer.

In one example, the gate electrode layer is formed on the pixel electrode layer, and the pixel electrode comprises only the second part of the pixel electrode layer.

In one example, the gate electrode has a dual-layer structure.

In one example, the gate electrode layer is formed under the pixel electrode layer, the gate electrode layer further comprises a second part, the second part of the gate electrode layer and the first part of the gate electrode layer are separated from each other, the second part of the gate electrode layer and the second part of the pixel electrode layer contact with each other and are positioned as face-to-face; the pixel electrode further comprises the second part of the gate electrode layer.

In one example, the gate electrode and the pixel electrode both have a dual-layer structure.

In one example, the array substrate is an OLED backplate, the second part of the gate electrode layer functions as a reflecting electrode of the OLED backplate.

In one example, the array substrate further comprises a gate insulating layer, an active layer, an etch stop layer, a source/drain electrode and a passivation layer, all of which are disposed on the gate electrode layer and the pixel electrode layer.

In one example, the array substrate further comprises a pixel defining layer disposed on the passivation layer.

In one example, the pixel electrode is electrically connected with the drain electrode through a via in the gate insulating layer.

In another aspect, there is provided a display device, which comprises the above-mentioned array substrate.

In yet another aspect, there is provided a method for manufacturing an array substrate, which comprises: forming a gate metal film and a pixel electrode film on a substrate, the gate metal film and the pixel electrode film being stacked in contact with each other; and forming a pattern comprising a gate electrode layer and a pixel electrode layer on the gate metal film and the pixel electrode film through a single patterning process with same mask.

In one example, the step of forming a gate metal film and a pixel electrode film on the substrate, the gate metal film and the pixel electrode film being stacked in contact with each other comprises:

forming a gate metal film and a pixel electrode film sequentially on the substrate.

In one example, the step of forming a pattern comprising a gate electrode layer and a pixel electrode layer on the gate metal film and the pixel electrode film through a single patterning process with same mask comprises:

forming a photoresist on the pixel electrode film;

exposing and developing the photoresist with a mask to form a photoresist-completely-remained region and a photoresist-completely-removed region, wherein the photoresist-completely-remained region corresponds to a region where a gate electrode and a pixel electrode are to be formed, and a photoresist-completely-removed region corresponds to the remaining regions;

etching the gate metal film and the pixel electrode film in the photoresist-completely-removed region and stripping off the residual photoresist;

In one example, the step of forming a gate metal film and a pixel electrode film on the substrate, the gate metal film and the pixel electrode film being stacked in contact with each other comprises:

forming a pixel electrode film and a gate metal film sequentially on the substrate.

In one example, the step of forming a pattern comprising a gate electrode layer and a pixel electrode layer on the gate metal film and the pixel electrode film through a single patterning process with same mask comprises:

forming a photoresist on the gate metal film;

exposing and developing the photoresist with a mask to form a photoresist-completely-remained region, a photoresist-partially-removed region and a photoresist-completely-removed region, wherein the photoresist-completely-remained region corresponds to a region where a gate electrode is to be formed, a photoresist-partially-removed region corresponds to a region where the pixel electrode is to be formed, and a photoresist-completely-removed region corresponds to the remaining regions;

etching the gate metal film and the pixel electrode film in the photoresist-completely-removed region, and ashing the photoresist to expose the gate metal film in the photoresist-partially-removed region;

etching the gate metal film in the photoresist-partially-removed region and stripping off the residual photoresist.

In one example, the method further comprises: forming a gate insulating layer, an active layer, an etch stop layer, a source-drain electrode and a passivation layer sequentially on the gate electrode layer and the pixel electrode layer.

In one example, the method further comprises: forming a pixel defining layer on the passivation layer.

### BRIEF DESCRIPTION OF THE DRAWINGS

In order to explain the technical solution of embodiments of the present invention more clearly, accompanying drawings of the embodiments will be introduced briefly below. Obviously, the accompanying drawings in the following description only relate to some embodiments of the present invention rather than limiting the present invention.

FIG. 1 is a cross-sectional view of an known array substrate;

FIG. 2 is a cross-sectional view of an array substrate provided in an embodiment of the present invention;

FIG. 3 is a cross-sectional view of another array substrate provided in an embodiment of the present invention;

FIGS. 4A and 4B are cross-sectional views of the array substrate after completing steps 301 and 303 in the method according to an embodiment of the present invention;

FIGS. 5A and 5B are cross-sectional views of the array substrate after completing steps 401 and 403 in the method according to an embodiment of the present invention.

### DETAILED DESCRIPTION

In order to make objects, technical details and advantages of the embodiments of the invention apparent, the technical solutions of the embodiments will be described in a clearly and fully understandable way in connection with the drawings related to the embodiments of the invention. Apparently, the described embodiments are just a part but not all of the embodiments of the invention. Based on the described embodiments herein, those skilled in the art can obtain other embodiment(s), without any inventive work, which should be within the scope of the invention.

Unless otherwise defined, all the technical and scientific terms used herein have the same meanings as commonly understood through a single of ordinary skill in the art to which the present invention belongs. The terms “first,” “second,” etc., which are used in the description and the claims of the present application for invention, are not intended to indicate any sequence, amount or importance, but distinguish various components. Also, the terms such as “a,” “an,” etc., are not intended to limit the amount, but indicate the existence of at lease one. The terms “comprises,” “comprising,” “comprises,” “comprising,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may comprise an electrical connection, directly or indirectly. “On,” “under,” “right,” “left” and the like are only used to indicate relative position relationship, and when the position of the object which is described is changed, the relative position relationship may be changed accordingly.

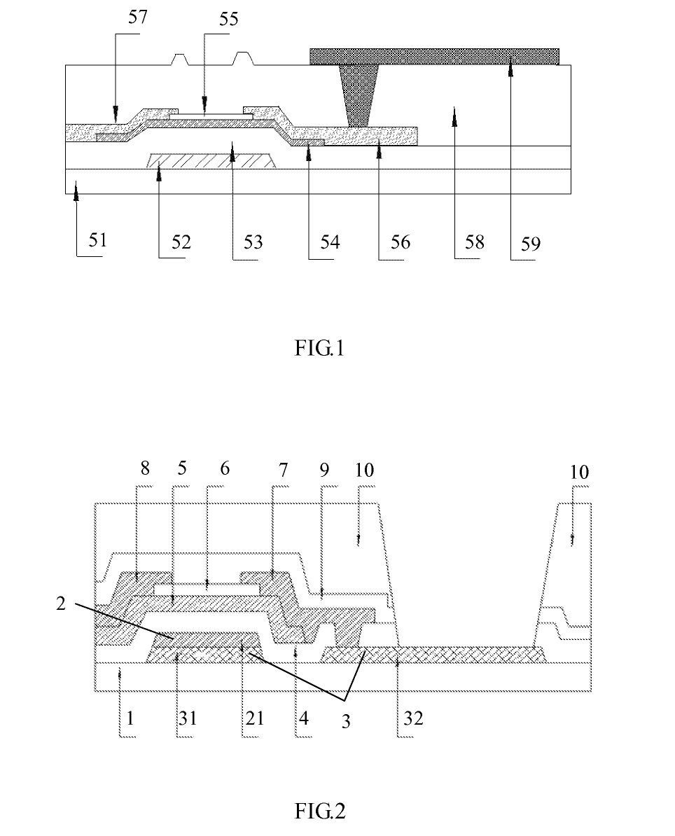

In the method for manufacturing the array substrate of FIG. 1, six masks are needed, which requires many masks and has relatively high production cost.

Referring to FIG. 2, an embodiment of the present invention provides an array substrate comprising: a substrate 1; a gate electrode layer 2 and a pixel electrode layer 3 which are formed on the substrate 1. The gate electrode layer 2 and the pixel electrode layer 3 are stacked and contact with each other. The pixel electrode layer 3 comprises a first part 31 and a second part 32 separated from each other; and the gate electrode layer comprises a first part 21.

Referring to FIG. 2, when the gate electrode layer 2 is formed on the pixel electrode layer 3, the gate electrode comprises the first part 31 of the pixel electrode layer 3 and the first part 21 of the gate electrode layer, whereas the pixel electrode comprises only the second part 32 of the pixel electrode layer 3. In one example, the first part 21 of the gate electrode layer 2 and the first part 31 of the pixel electrode 3 have equal size (for example equal width) and are positioned as facing to each other so as to facilitate designing and implementing patterning process.

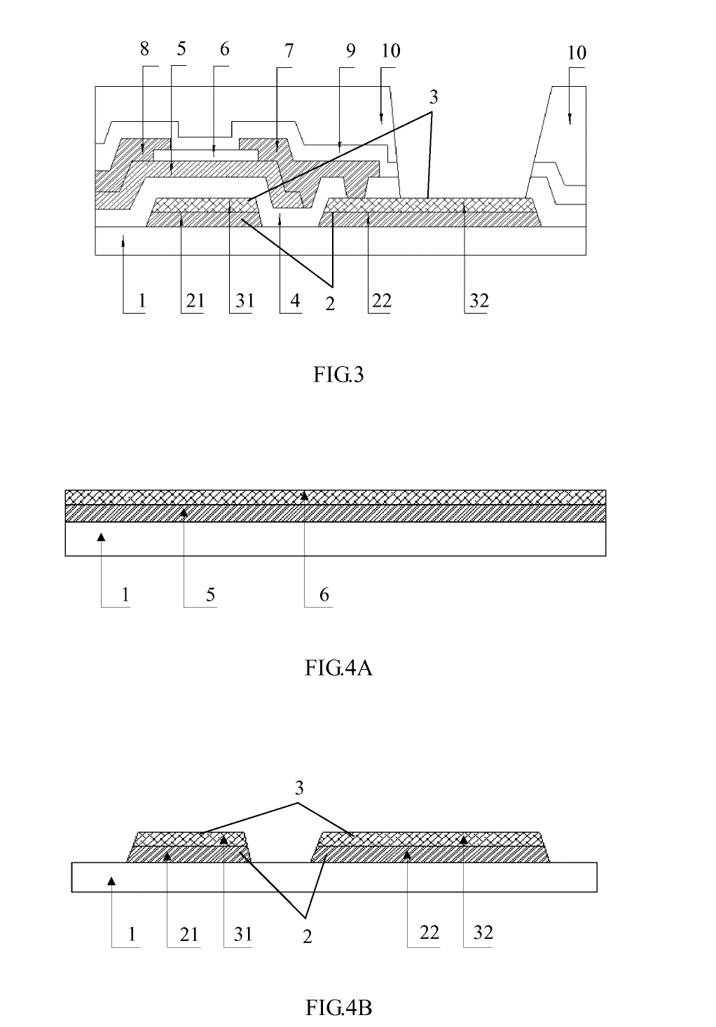

Alternatively, referring to FIG. 3, when the gate electrode layer 2 is formed under the pixel electrode layer 3, the gate electrode layer 2 comprises a first part 21 and a second part 22 separated from each other, and the pixel electrode layer 3 comprises a first part 31 and a second part 32 separated from each other. The first part 21 of the gate electrode layer 2 and the first part 31 of the pixel electrode layer 3 formed thereon contact with each other to constitute a gate electrode of thin film transistor. The second part 22 of the gate electrode layer 2 and the second part 32 of the pixel electrode layer 3 formed thereon contact with each other to constitute a pixel electrode. In one example, the first part 21 of the gate electrode layer 2 and the first part 31 of the pixel electrode 3 have equal size and are positioned as facing to each other, the second part 22 of the gate electrode layer 2 and the second part 32 of the pixel electrode 3 have equal size and are positioned as facing to each other so as to facilitate designing and implementing patterning process.

In the above-mentioned embodiment, the array substrate further comprises a gate insulating layer 4, an active layer 5, an etch stop layer 6, a source electrode 7, a drain electrode 8 and a passivation layer 9, all of which are disposed over both the gate electrode and the pixel electrode. As illustrated in FIGS. 2 and 3, a drain electrode 7 is electrically connected with the second part 32 of the pixel electrode layer 3 through a via in the gate insulating layer 4.

In all embodiments of the present invention, the material and thicknesses of the respective layers may be selected depending on practical requirements. For example, the gate insulating layer 4 is a single-layer film made of any one of SiOx, SiNx, HfOx, SiON, and AlOx, or a multilayer film made of any two or more thereof. If the gate insulating layer 4 has a SiNx/SiOx laminated structure, or a SiNx/SiON/SiOx laminated structure, the total thickness of the film layer is in the range from 100 nm to 600 nm.

As another example, the active layer 5 is a film containing elements, such as In, Ga, Zn, O, or Sn. For example, the film contains O element and any two or more other elements, such as IGZO, IZO, InSnO or InGaSnO. The active layer 5 is made of for example IGZO or IZO with a thickness of 10˜100 nm.

As another example, the etch stop layer 6 is a single-layer film made of any one of SiOx, SiNx, HfOx and AlOx, or a multilayer film made of two or more of them.

As another example, both the source electrode 7 and the drain electrode 8 are single-layer films made of any one of Mo, MoNb, Al, AlNd, Ti, and Cu or multilayer films made of any two or more of them.

In one example, in case the array substrate is an OLED backplate, the array substrate further comprises a pixel defining layer 10.

The pixel defining layer 10 is for example an organic insulating layer, which has low moisture content and photo-sensitive property similar to that of the photoresist.

In one example, in case the array substrate illustrated in FIG. 3 is an OLED backplate, the second part 22 of the gate electrode layer 2 functions as the reflecting electrode of the OLED backplate.

In one example, the gate electrode layer 2 is a single-layer film made of any one of molybdenum, molybdenum niobium alloy, aluminum, aluminum neodymium alloy, titanium and copper, or a multilayer film made of two or more of them. The gate electrode layer 2 has a thickness of 100 nm-500 nm.

In one example, the pixel electrode layer 3 is an ITO film with a thickness of 20 nm-150 nm.

It is to be noted that description of the material or thickness of the respective layers in the present embodiment is only for illustration and the present invention is not limited thereto.

In the array substrate of the above-mentioned embodiment, the gate electrode metal layer and the pixel electrode layer are stacked and contact with each other, therefore in the patterning process of the manufacturing process, the two layers are formed by only one patterning process with the same mask, which reduces the number of masks and the production cost.

An embodiment of the present invention further provides a display device comprising the array substrate provided in the above-mentioned embodiments.

An embodiment of the present invention further provides a method for manufacturing an array substrate, the method comprises the following steps:

201, forming a gate metal film and a pixel electrode film on the substrate, the gate metal film and the pixel electrode film being stacked in contact with each other; and

202, forming a pattern comprising the gate electrode layer and the pixel electrode layer on the gate metal film and the pixel electrode film through a single patterning process with the same mask.

In one example, in case the pixel electrode film is formed on the gate metal film, the formed gate electrode layer comprises a first part and a second part separated from each other, the formed pixel electrode layer comprises a first part and a second part separated from each other; the first part of the gate electrode layer and the first part of the pixel electrode layer formed on the first part of the gate electrode layer contact with each other to constitute a gate electrode of thin film transistor, the second part of the gate electrode layer and the second part of the pixel electrode layer formed on the second part of the gate electrode layer contact with each other to constitute a pixel electrode. Alternatively, in case the gate metal film is formed on the pixel electrode film, the formed gate electrode layer comprises a first part that is formed only on the first part of the pixel electrode layer. Here, the first part of the pixel electrode layer and the first part of the gate electrode layer contact with each other to constitute a gate electrode of thin film transistor, and the second part of the pixel electrode layer constitutes a pixel electrode.

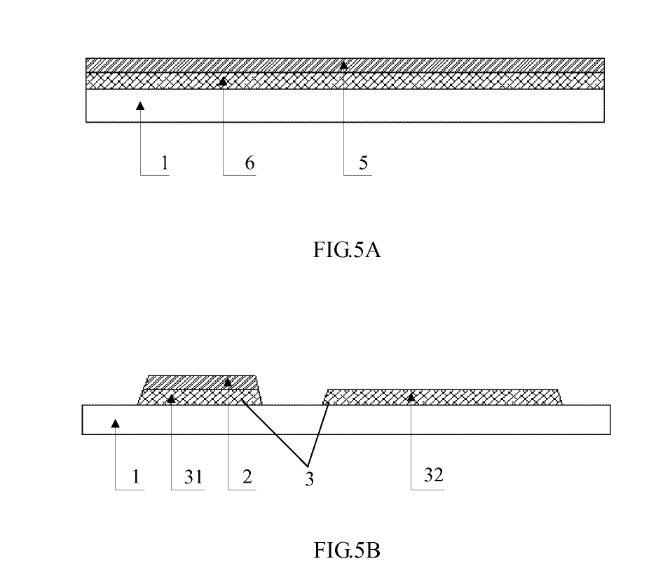

Therefore, in the present disclosure, the gate electrode layer may be located over the pixel electrode layer, and may also be located under the pixel electrode layer. For clarity of description, two examples of the manufacturing method of array substrate will be described below with respect to FIGS. 4A, 4B, 5A, and 5B.

In one example, as illustrated in FIGS. 4A and 4B, the method for manufacturing an array substrate comprises the following steps:

301. forming a gate metal film 5 and a pixel electrode film 6 (such as a transparent conductive film) sequentially on the substrate 1. As illustrated in FIG. 4A, the pixel electrode film 6 is formed over the gate metal film 5.

302. forming a photoresist on the pixel electrode film 6.

303. exposing and developing the photoresist with a mask to form a photoresist-completely-remained region and a photoresist-completely-removed region, where the photoresist-completely-remained region corresponds to a region where a gate electrode and a pixel electrode are to be formed, and a photoresist-completely-removed region corresponds to the remaining regions.

304. etching the gate metal film 5 and the pixel electrode film 6 in the photoresist-completely-removed region, and stripping off the residual photoresist to form patterns of gate electrode layer 2 and pixel electrode layer 3 as illustrated in FIG. 4B, where the gate electrode layer 2 comprises a first part 21 and a second part 22, and the pixel electrode layer 3 comprises a first part 31 and a second part 32. Here, the first part 21 of the pixel electrode layer 2 and the first part 31 of the gate electrode layer 3 constitute the gate electrode, and the second part 22 of the pixel electrode layer 2 and the second part 32 of the pixel electrode layer 3 constitute the pixel electrode.

In one example, in step 304, the gate metal film 5 and the pixel electrode film 6 are etched with different etchants respectively to form patterns of gate electrode layer 2 and pixel electrode layer 3.

305. forming a gate insulating layer 4, an active layer 5, an etch stop layer 6, a source-drain electrode 7 and a passivation layer 8 sequentially on the substrate that have gone through the above-mentioned steps, as illustrated in FIG. 2.

In one example, in case the array substrate is an OLED backplate, the above-mentioned method further comprises: step 306, forming a pixel defining layer 10. Finally, an array substrate as illustrated in FIG. 2 is obtained.

In the above-mentioned method for manufacturing the array substrate, the gate metal film and the pixel electrode film are sequentially deposited and stacked in contact with each other so as to form a composite film, therefore only the same and one mask is required to form patterns of gate electrode layer and pixel electrode layer on the composite film through a single patterning process, thereby reducing the number of masks and the production cost. At the same time, in case the array substrate is used as an OLED backplate, the second part of the gate electrode layer may be used as reflecting electrode of the OLED backplate.

In another example, as illustrated in FIGS. 5A and 5B, the method for manufacturing an array substrate comprises the following steps:

401. forming a pixel electrode film 6 (such as a transparent conductive film) and a gate metal film 5 sequentially on the substrate 1. As illustrated in FIG. 5A, the gate metal film 5 is formed over the pixel electrode film 6.

402. forming a photoresist on the gate metal film 5.

403. exposing and developing the photoresist with a mask to form a photoresist-completely-remained region, a photoresist-partially-removed region and a photoresist-completely-removed region, where the photoresist-completely-remained region corresponds to a region where a gate electrode is to be formed, a photoresist-partially-removed region corresponds to a region where a pixel electrode is to be formed and a photoresist-completely-removed region corresponds to the remaining region.

404. etching the gate metal film 5 and the pixel electrode film 6 in the photoresist-completely-removed region and ashing the photoresist to expose the gate metal film 5 in the photoresist-partially-removed region.

405. etching the gate metal film 5 in a photoresist-partially-removed region, and stripping off the residual photoresist to form patterns of gate electrode layer 2 and pixel electrode layer 3, as illustrated in FIG. 6B. The gate electrode layer 2 comprises a first part, and the pixel electrode layer 3 comprises a first part 31 and a second part 32. Here, the first part of the gate electrode layer 2 and the first part 31 of the pixel electrode layer 3 constitute the gate electrode, and the second part 32 of the pixel electrode layer 3 constitutes the pixel electrode.

406. forming a gate insulating layer 4, an active layer 5, an etch stop layer 6, a source-drain electrode 7 and a passivation layer 8 sequentially on the substrate that have gone through the above-mentioned steps, as illustrated in FIG. 3.

In one example, in case the array substrate is an OLED backplate, the above-mentioned manufacturing method further comprises: step 407, forming a pixel defining layer 10. Finally, an array substrate as illustrated in FIG. 3 is obtained.

In the above-mentioned method for manufacturing the array substrate, the gate metal film and the pixel electrode film are sequentially deposited and stacked in contact with each other so as to form a composite film, therefore only the same and one mask is required to form patterns of gate electrode layer and pixel electrode layer on the composite film through a single patterning process, thereby reducing the number of masks and the production cost.

All embodiments of the present invention are described with respect to a bottom gate TFT array substrate as an example. A top gate TFT array substrate has a similar configuration. One skilled in the art can easily contemplate the configuration and manufacturing method of a top gate TFT array substrate according to the configuration and manufacturing method of the bottom gate TFT array substrate of embodiments of the present invention.

What is described above is related to the illustrative embodiments of the disclosure only and not limitative to the scope of the disclosure; the scopes of the disclosure are defined by the accompanying claims.

The present application claims priority from Chinese Application Serial Number 201310487699.4 filed on Oct. 17, 2013, the disclosure of which is hereby incorporated by reference herein in its entirety.

1. An array substrate, comprising: a substrate; a gate electrode layer and a pixel electrode layer both formed on the substrate,
wherein the gate electrode layer and the pixel electrode layer are stacked in contact with each other; the pixel electrode layer comprises a first part and a second part separated from each other, the gate electrode layer comprises a first part, the first part of the gate electrode layer and the first part of the pixel electrode layer are positioned as face-to-face; and
a gate electrode comprises the first part of the gate electrode layer and the first part of the pixel electrode layer, and a pixel electrode comprises the second part of the pixel electrode layer.

2. The array substrate of claim 1, wherein the gate electrode layer is formed on the pixel electrode layer, and the pixel electrode comprises only the second part of the pixel electrode layer.

3. The array substrate of claim 2, wherein the gate electrode has a dual-layer structure.

4. The array substrate of claim 1, wherein the gate electrode layer is formed under the pixel electrode layer, the gate electrode layer further comprises a second part, the second part of the gate electrode layer and the first part of the gate electrode layer are separated from each other, the second part of the gate electrode layer and the second part of the pixel electrode layer contact with each other and are positioned as face-to-face; the pixel electrode further comprises the second part of the gate electrode layer.

5. The array substrate of claim 4, wherein the gate electrode and the pixel electrode both have a dual-layer structure.

6. The array substrate of claim 4, wherein the array substrate is an OLED backplate, the second part of the gate electrode layer functions as a reflecting electrode of the OLED backplate.

7. The array substrate of claim 1, further comprising: a gate insulating layer, an active layer, an etch stop layer, a source-drain electrode and a passivation layer, all of which are disposed on the gate electrode layer and the pixel electrode layer.

8. The array substrate of claim 7, further comprising: a pixel defining layer disposed on the passivation layer.

9. The array substrate of claim 7, wherein the pixel electrode is electrically connected with the drain electrode through a via in the gate insulating layer.

10. A display device, comprising the array substrate of claim 1.

11. A method for manufacturing an array substrate, comprising:
forming a gate metal film and a pixel electrode film on a substrate, the gate metal film and the pixel electrode film being stacked in contact with each other; and
forming a pattern comprising a gate electrode layer and a pixel electrode layer on the gate metal film and the pixel electrode film through a single patterning process with same mask.

12. The method of claim 11, wherein the step of forming a gate metal film and a pixel electrode film on the substrate, the gate metal film and the pixel electrode film being stacked in contact with each other comprises:
forming a gate metal film and a pixel electrode film sequentially on the substrate.

13. The method of claim 12, wherein the step of forming a pattern comprising a gate electrode layer and a pixel electrode layer on the gate metal film and the pixel electrode film through a single patterning process with same mask comprises:
forming a photoresist on the pixel electrode film;
exposing and developing the photoresist with a mask to form a photoresist-completely-remained region and a photoresist-completely-removed region, wherein the photoresist-completely-remained region corresponds to a region where a gate electrode and a pixel electrode are to be formed, and a photoresist-completely-removed region corresponds to the remaining regions;
etching the gate metal film and the pixel electrode film in the photoresist-completely-removed region and stripping off the residual photoresist.

14. The method of claim 11, wherein the step of forming a gate metal film and a pixel electrode film on the substrate, the gate metal film and the pixel electrode film being stacked in contact with each other comprises:
forming a pixel electrode film and a gate metal film sequentially on the substrate.

15. The method of claim 14, wherein the step of forming a pattern comprising a gate electrode layer and a pixel electrode layer on the gate metal film and the pixel electrode film through a single patterning process with same mask comprises:
forming a photoresist on the gate metal film;
exposing and developing the photoresist with a mask to form a photoresist-completely-remained region, a photoresist-partially-removed region and a photoresist-completely-removed region, wherein the photoresist-completely-remained region corresponds to a region where a gate electrode is to be formed, a photoresist-partially-removed region corresponds to a region where the pixel electrode is to be formed, and a photoresist-completely-removed region corresponds to the remaining regions;
etching the gate metal film and the pixel electrode film in the photoresist-completely-removed region, and ashing the photoresist to expose the gate metal film in the photoresist-partially-removed region;
etching the gate metal film in the photoresist-partially-removed region and stripping off the residual photoresist.

16. The method of claim 11, further comprising:
forming a gate insulating layer, an active layer, an etch stop layer, a source-drain electrode and a passivation layer sequentially on the gate electrode layer and the pixel electrode layer.

17. The method of claim 16, further comprising:
forming a pixel defining layer on the passivation layer.

18. The display device of claim 10, wherein the gate electrode layer is formed on the pixel electrode layer, and the pixel electrode comprises only the second part of the pixel electrode layer.

19. The display device of claim 18, wherein the gate electrode has a dual-layer structure.

20. The display device of claim 10, wherein the gate electrode layer is formed under the pixel electrode layer, the gate electrode layer further comprises a second part, the second part of the gate electrode layer and the first part of the gate electrode layer are separated from each other, the second part of the gate electrode layer and the second part of the pixel electrode layer contact with each other and are positioned as face-to-face; the pixel electrode further comprises the second part of the gate electrode layer.
